(19) United States
(12) Patent Application Publication
(10) Pub. No.: US 2022/0199507 A1
(43) Pub. Date: Jun. 23, 2022

(54) MULTI-LAYERED PACKAGING FOR SUPERCONDUCTING QUANTUM CIRCUITS

(71) Applicant: International Business Machines Corporation, Armonk, NY (US)

(72) Inventors: David Abraham, Croton, NY (US); Oliver Dial, Yorktown Heights, NY (US); John Michael Cotte, New Fairfield, CT (US); Joseph Robert Suttle, Chappaqua, NY (US)

(21) Appl. No.: 17/130,640

(22) Filed: Dec. 22, 2020

(51) Int. Cl. H01L 23/498; H01L 21/48; H01L 39/04

(52) U.S. Cl. CPC H01L 23/49827; H01L 23/49822; H01L 23/49816; H01L 39/04; H01L 21/486; H01L 21/4857; H01L 23/49888

(57) ABSTRACT

A quantum semiconductor device includes a qubit chip; an interposer chip, with a handler, including a through-silicon-via (TSV) coupled to a first side of the qubit chip. A multi-level wiring (MLW) layer contacts an underside of the interposer chip and coupling to the top side of the handler, the TSV facilitates an electrical signal connection between the MLW layer, a topside of the interposer chip and the qubit chip, wherein structure of the device mitigates signal cross-talk across respective lines of the MLW layer.

### TECHNICAL FIELD

The subject disclosure relates to using superconducting through-silicon vias (TSVs) to access a high-quality surface on a backside of a qubit or interposer wafer wherein connections to and from signal TSVs are designed to minimize reflections.

### BACKGROUND

Quantum computing generally utilizes quantum-mechanical phenomena to perform computing and information processing functions. Quantum computers operate on quantum bits that comprise superpositions of both 0 and 1, can entangle multiple quantum bits, and utilize interference. A qubit (e.g., quantum binary digit) is a quantum mechanical analogue of a classical bit. Superconducting qubits offer a promising path towards constructing fully-operational quantum computers as it can exhibit quantum-mechanical behavior (e.g., facilitating quantum information processing) at a macroscopic level. Superconducting qubits are multilevel systems, and the two lowest energy levels (0 and 1) constitute the qubit. One of the challenges in quantum computing is to protect quantum information (e.g., qubit state) and mitigate errors during dynamic quantum computation. A typical quantum circuit packaging includes two chips with only the inward facing surfaces utilized for devices and signals delivery/readout. The qubit chip surface is utilized for qubits and the interconnections which allow qubits to entangle. In the current design, a qubit may require on average ˜1.1 to 3 or more wires within a single silicon chip. While assembling a quantum device, a chip with qubits is bump bonded to an interposer. The interposer is then bump bonded to a printed circuit board (PCB) or similar and the signals are extracted. If a 1000-qubit chip is utilized with, for example, 1100 to 3000 wires for qubit measurement and control, all of which escape to the periphery of the interposer, then the complexity of the wire circuitry may lead to high cross-talk. Thus, the problem arises in providing high-quality connections from a qubit within a single silicon chip while maintaining low crosstalk.

### SUMMARY

The following presents a summary to provide a basic understanding of one or more embodiments of the invention. This summary is not intended to identify key or critical elements, delineate scope of particular embodiments or scope of claims. Its sole purpose is to present concepts in a simplified form as a prelude to the more detailed description that is presented later. In one or more embodiments described herein, systems, computer-implemented methods, apparatus and/or computer program products facilitate using superconducting through-silicon vias to access the high-quality surface on the back side of the qubit or interposer wafer wherein the connections to and from signal TSVs are designed to minimize reflections.

In accordance with an embodiment, a quantum semiconductor device, comprises a qubit chip; an interposer chip, with a handler, including a through-silicon-via (TSV) coupled to top surface of the interposer chip through bump bonds to a bottom surface of the qubit chip; and a multi-level wiring (MLW) layer contacting an underside of the interposer chip and coupling to the top side of the handler, the TSV facilitating an electrical signal connection between the MLW layer, a topside of the interposer chip and the qubit chip, wherein the structure of the device mitigates signal cross-talk across respective lines of the MLW layer.

In an aspect, the TSV provides an electrical signal connection from the MLW layer to the topside of the interposer chip.

In another aspect, the interposer chip is connected to a printed circuit board (PCB), laminate or flex wiring harness wiring harness using periphery bump bonds on the top side of the interposer chip.

In yet another aspect the periphery bump bonds are electrically connected to the wiring layer.

In an aspect, the MLW layer comprises a multilayer wiring structure with interlayer and superconducting layers.

In another aspect, the MLW layer facilitates complex routing and effective radio frequency transmission.

In yet another aspect, a backside of the MLW layer performs as a redistribution wiring layer.

In an aspect, connections to and from the TSV minimize reflections.

In another aspect, a characteristic impedance of the MLW, the TSV, and routing on the interposer chip are matched to facilitate signal routing.

In accordance with an embodiment, a method, comprises: forming a qubit chip; forming an interposer chip, with a handler, including a through-silicon-via (TSV) coupled to top surface of the interposer chip through bump bonds to a bottom surface of the qubit chip; and forming a multi-level wiring (MLW) layer contacting an underside of the interposer chip and coupling to the top side of the handler, the TSV facilitating an electrical signal connection between the MLW layer, a topside of the interposer chip and the qubit chip, wherein structure of the device mitigates signal cross-talk across respective lines of the MLW layer.

In an aspect, the method utilizes the TSV to provide an electrical signal connection from the MLW layer to the topside of the interposer chip.

In an aspect, the method connects the interposer chip to a printed circuit board (PCB), laminate or flex wiring harness using periphery bump bonds on the top side of the interposer chip.

In another aspect, the method electrically couples the periphery bump bonds to the MLW layer.

In an aspect, the method couples a wiring layer with a multilayer wiring structure with interlayer and superconducting layers.

In yet another aspect, the method utilizes the MLW layer to facilitate complex routing and effective radio frequency transmission.

In an aspect, the method utilizes a backside of the MLW layer to perform as a redistribution wiring layer.

In an aspect, the method utilizes connections to and from the TSV to minimize reflections.

In still another aspect, the method matches a characteristic impedance of the MLW, the TSV, and routing on the interposer chip to facilitate signal routing.

In accordance with another embodiment, a quantum semiconductor device, comprises: an interposer chip, with a handler, including a through-substrate-via (TSV), bump bonded to a qubit chip; a multi-level wiring (MLW) layer, contacting an underside of the interposer chip, the TSV facilitating an electrical signal connection between the MLW layer, a topside of the interposer chip and the qubit chip, wherein structure of the device mitigates signal cross-talk across respective lines of the MLW layer; and a set of through-silicon vias (TSVs) connected to the qubit chip for grounding and carrying signals down to a backside of the interposer chip; wherein the interposer chip comprises a second TSV that provides an electrical signal connection from the wiring layer to the top side of the interposer chip. In an aspect, the interposer chip is connected to a printed circuit board (PCB), laminate or flex wiring harness using periphery bump bonds on the top side of the interposer chip.

### DESCRIPTION OF THE DRAWINGS

FIG. 1 illustrates a block diagram of an example system implementation for a multi-layered packaging for superconducting quantum circuits.

FIG. 2 illustrates an example of quantum circuit packaging and qubit chip surface.

FIG. 3 illustrates an example qubit chip surface top view lattice.

FIG. 4 illustrates an example flowchart for creating an improved multi-layered packaging for quantum circuits.

FIG. 5 illustrates an example of a multi-layer superconducting device.

FIG. 6 illustrates an example schematic within the interposer wafer.

FIG. 7 illustrates a block diagram of an example, non-limiting, operating environment in which one or more embodiments described herein can be facilitated.

FIG. 8 illustrates a block diagram of an example, non-limiting, cloud computing environment in accordance with one or more embodiments of the subject disclosure.

FIG. 9 illustrates a block diagram of example, non-limiting, abstraction model layers in accordance with one or more embodiments of the subject disclosure.

### DETAILED DESCRIPTION

The following detailed description is merely illustrative and is not intended to limit embodiments and/or application or utilizes of embodiments. Furthermore, there is no intention to be bound by any expressed or implied information presented in the preceding Summary section, or in the Detailed Description section. One or more embodiments are now described with reference to the drawings, wherein like reference numerals are utilized to refer to like elements throughout. In the following description, for purposes of explanation, numerous specific details are set forth in order to provide a more thorough understanding of the one or more embodiments. It is evident; however, in various cases, that the one or more embodiments can be practiced without these specific details.

The subject disclosure relates generally to systems and methods that utilize superconducting TSVs to access a surface on a backside of a qubit or interposer wafer. Multi-layered packaging is incorporated for superconducting quantum circuits wherein the connections to and from signal TSVs are designed to minimize reflections, loss and crosstalk.

Quantum computation utilizes a qubit as its essential unit instead of a classical computing bit. The qubit (e.g., quantum binary digit) is the quantum-mechanical analog of the classical bit. Whereas classical bits can employ on only one of two basis states (e.g., 0 or 1), qubits can employ on superpositions of those basis states (e.g., α|0 [symbol] +β|1 [symbol] , where α and β are complex scalars such that |α|²+|β|²=1), allowing several qubits to theoretically hold exponentially more information than the same number of classical bits. Thus, quantum computers (e.g., computers that employ qubits instead of solely classical bits) can, in theory, quickly solve problems that can be extremely difficult for classical computers. The bits of a classical computer are simply binary digits, with a value of either 0 or 1. Almost any device with two distinct states can serve to represent a classical bit: a switch, a valve, a magnet, a coin, etc. Qubits, partaking of the quantum mystique, can occupy a superposition of 0 and 1 states. It's not that the qubit can have an intermediate value, such as 0.63; when the state of the qubit is measured, the result is either 0 or 1. But in the course of a computation, a qubit can act as if it were a mixture of states—for example: 63 percent 0 and 37 percent 1. General quantum programs require coordination of quantum and classical parts of a computation. In quantum programs, identifying processes and abstractions involved in specifying a quantum algorithm, transforming the algorithm into executable form, running an experiment or simulation, and analyzing the results is valuable. A notion throughout these processes utilizes intermediate representations. An intermediate representation (IR) of computation is neither its source language description nor the target machine instructions, but something in between. Compilers may utilize several IRs during the process of translating and optimizing a program. The input is a source code describing a quantum algorithm and compile time parameter(s). The output is a combined quantum/classical program expressed using a high-level IR. A distinction between a quantum and classical computer is that the quantum computer is probabilistic, thus measurements of algorithmic outputs provide a proper solution within an algorithm specific confidence interval. The computation is then repeated until a satisfactory probable certainty of solution can be achieved.

By processing information using laws of quantum mechanics, quantum computers offer novel ways to perform computation tasks such as molecular calculations, optical photons, optimization, and many more. Many algorithms are introduced to perform such computational tasks efficiently. Also, many promising solid-state implementations of qubits have been demonstrated, including superconducting qubits of diverse flavors, spin qubits, and, charge qubits in various material systems. Typical quantum circuit packaging includes two chips with only inward facing surfaces utilized for devices and signal delivery/readout. The qubit chip surface is utilized for qubits and the interconnections which allow qubits to entangle. The interposer surface is utilized for readout resonators, filters, and feed and readout lines. Although it is possible to mix functions between these two layers, the intersecting patterns of respective lines means that bump bonds are utilized to provide crossovers in these locations. Having only two surfaces arranged with vertical connections limits the kind of structures that can be built. For example, in large devices, there will be many interior qubits that need to connect to control and readout circuitry via bumps at the periphery of the interposer. Routing wires from an interior of the chip out to an edge for all of these qubits is problematic due to there are only two wiring surfaces available and so there will inevitably be conflicts between this wiring and qubits closer to the edge (along with their respective readout resonators, filters, etc). These conflicts can lead to issues with crosstalk and loss as well as complicated layout challenges.

In general, there are various processes used to form a micro-chip that will be packaged into an integrated circuit (IC). In particular, semiconductor doping is the modification of electrical properties by doping, for example, transistor sources and drains, generally by diffusion and/or by ion implantation. Moreover, films of both conductors (e.g., poly-silicon, aluminum, copper, etc.) and insulators (e.g., various forms of silicon dioxide, silicon nitride, etc.) are used. Various transistors can be built and wired together by creating structures of these various components to form complex circuitry of a modern microelectronic device. One of the fundamental fabrication processes is semiconductor lithography wherein patterns on the semiconductor substrate is formed for subsequent transfer of the pattern to the substrate.

Semiconductor devices are used in variety of electronic and electro-optical applications. ICs are typically formed from various circuit configurations of semiconductor devices such as transistors, capacitors, resistors and conductive interconnect layers formed on semiconductor wafers. In a semiconductor fabrication process, conductive interconnect layers along with semiconductor devices are fabricated on a single wafer. The interconnect layers are connected by a network of holes (or vias) formed through the IC. In particular, a through-silicon via (TSV) is an electrical contact that passes completely through a semiconductor wafer.

Fabricating intricate structures of conductive interconnect layers and vias within an IC is a process intensive and cost sensitive portion of a semiconductor IC fabrication. Thus, embodiments herein propose to utilize superconducting TSVs to access a wiring surface on a back side of a qubit or interposer wafer. Embodiments facilitate superconducting TSVs to access a surface on the back side of a qubit or an interposer wafer. In the multi-layered packaging, the backside wiring may act as a redistribution layer and the TSVs carrying signals back up to the interposer surface may aid to minimize reflections. Moreover, the connections within the interposer wafer to the metal lines facilitate complex signal transfers.

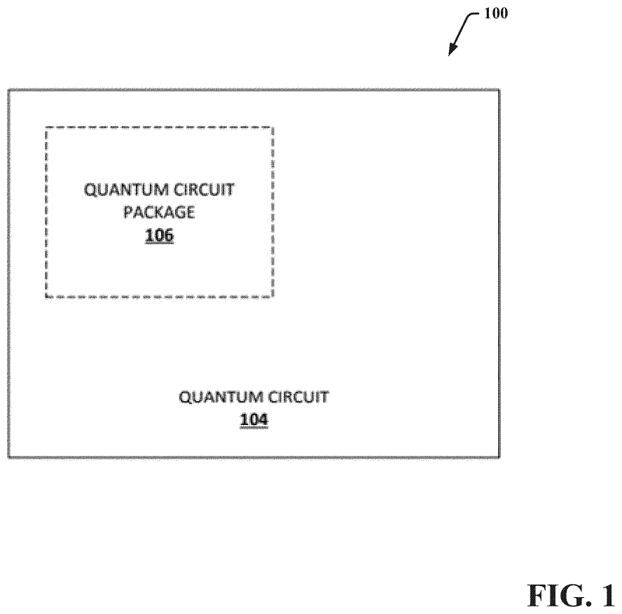

FIG. 1 illustrates a block diagram of an example system 100 that can access data and process that data using variable computing components depicted in accordance with one or more embodiments described herein. The system 100 can facilitate a process of assessing and identifying large amounts of various forms of data, using machine learning, and training a neural network or other type of model. The system 100 can also generate predictive recommendations to an individual level with context in accordance with one or more embodiments described herein. Aspects of systems (e.g., system 100 and the like), apparatuses or processes explained in this disclosure can constitute machine-executable component(s) embodied within machine(s), e.g., embodied in one or more computer readable mediums (or media) associated with one or more machines. Such component(s), when executed by the one or more machines, e.g., computer(s), computing device(s), virtual machine(s), etc. can cause the machine(s) to perform operations described herein. Repetitive description of like elements employed in one or more embodiments described herein is omitted for sake of brevity.

The system 100 can facilitate a process of assessing and identifying a large amount of various forms of data. The system 100 can also generate predictive recommendations to an individual level resulting in a context in accordance with one or more embodiments described herein. Aspects of systems (e.g., system 100 and the like), apparatuses or processes explained in this disclosure can constitute machine-executable component(s) embodied within machine(s), e.g., embodied in one or more computer readable mediums (or media) associated with one or more machines. Such component(s), when executed by the one or more machines, e.g., computer(s), computing device(s), virtual machine(s), etc. can cause the machine(s) to perform the operations described. Repetitive description of like elements employed in one or more embodiments described herein is omitted for sake of brevity.

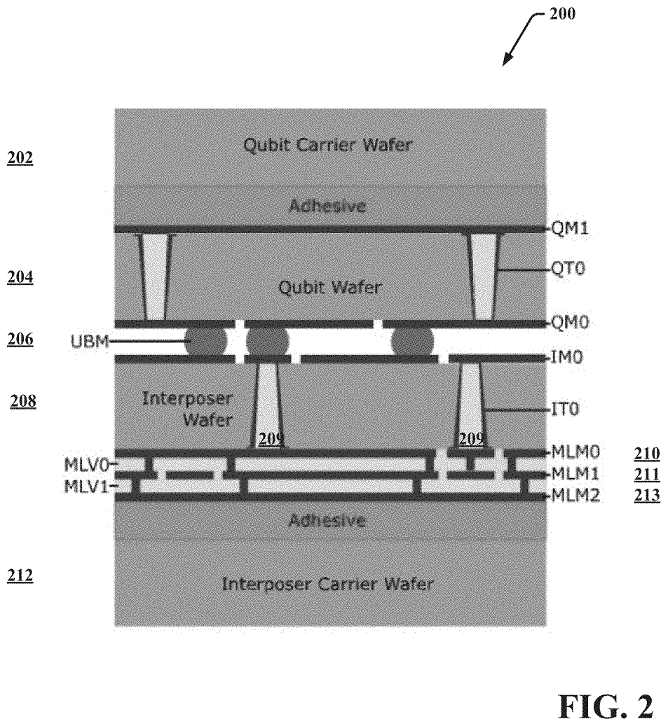

System 100 can optionally include a server device, one or more networks and one or more devices (not shown). The system 100 can include or otherwise be associated with a quantum circuit 104 incorporating a quantum circuit package 106, that can operative couple various components shown in greater detail in FIGS. 2, 3, and 5 including, but not limited to a qubit chip; an interposer chip, with a handler, including a through-silicon-via (TSV) coupled (e.g., operatively coupled) to a first side of the qubit chip; and a multi-level wiring (MLW) layer contacting an underside of the interposer chip, the TSV facilitating an electrical signal connection between the MLW layer, a topside of the interposer chip and the qubit chip, wherein structure of the device mitigates signal cross-talk across respective lines of the MLW layer, and produces a desired output with high quality signal transfer and low cross-talk.

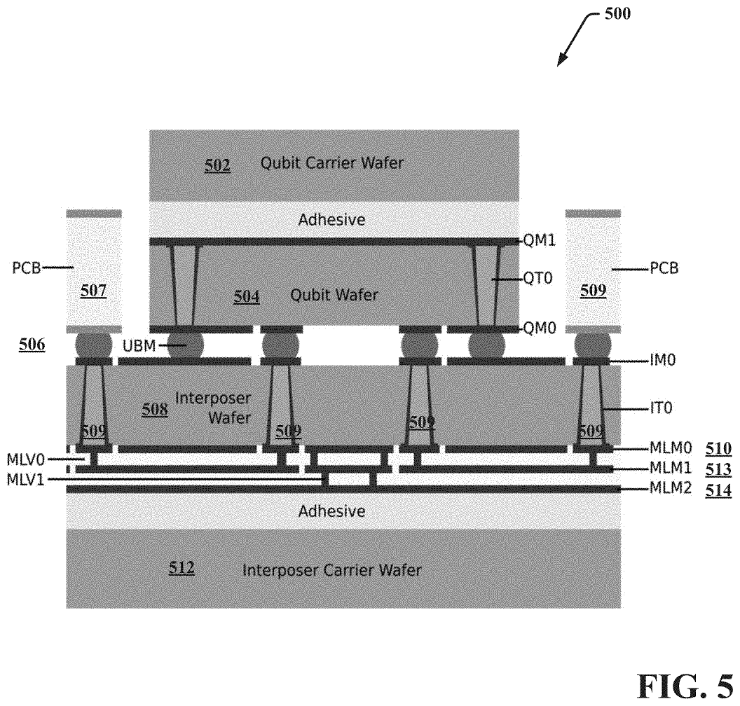

In an implementation, the quantum circuit 104 incorporates a multi-layered structure as shown in FIG. 2 in a specific non-limiting implementation, for example, with a qubit wafer 204 (or qubit chip) with or without protective TSVs, and an interposer layer (or interposer wafer or interposer chip) 208 that is bump bonded (using bump bonds (UBM) 206) to the qubit chip 204. It is to be appreciated that although embodiments described herein utilize bump bonds, other suitable techniques or mechanisms (e.g., capacitive coupling) can be utilized. A multi-level wiring (MLW) layer, MLM0 210, MLM1 211, MLM2 213 is directly contacting an underside of the interposer chip 208, insulating layers MLV0 and MLV1 isolate wiring of the MLW layer 210, 211, 213, and through-substrate-vias (TSVs) 209 provide electrical signal connection to the MLW layer from the topside of the interposer chip 208. The interposer chip 208 can be connected to a printed circuit board (PCB), laminate, or flex using periphery bump bonds on the top surface of an interposer chip as shown in and discussed further in connection with FIG. 5. The periphery bump bonds 206 are electrically connected to the MLW layer 210, 211, 213 utilizing the TSVs 209. The multilayer wiring MLW structure includes an interlayer and superconducting layers. The device 200 has multi-level wiring (MLW) to allow complex routing and effective radio frequency transmission. The backside multi-level wiring can perform as a redistribution layer. Connections to and from TSV signals are designed to minimize reflections and characteristic impedance of the MLW, TSV, and routing on the interposer chip can be matched to facilitate signal routing and produce a desired output.

In a specific non-limiting implementation, for example, a TSV is formed by opening through the semiconductor wafer at a desired location, and then filling the via with conductive material, thereby providing a solid metal contact that extends from a front side of the wafer to a back side of the wafer. Alternatively, in prior art, a thin superconducting film may be used and then filled with a non-superconducting material which may be dielectric such as SiO2, poly-silicon, or other. Some considerations in forming TSVs include the conductive metal fill of the via wherein it is substantially planar with the front side of the wafer and the back side of the wafer to be compatible with downstream processing techniques. To minimize fabrications problems, it is desirable to fill vias completely in order to facilitate subsequent processing steps such as spinning on of photoresist materials. It is also desirable to facilitate fabrication methodologies and structures for TSVs that utilize high purity low-void conductive material and are less dependent than known techniques on aspect-ratio of the vias. In a multilevel IC configuration, for example, a TSV can be used to form vertical interconnections between a semiconductor device located on one level of the IC and an interconnect layer located on another level of the IC. As IC feature sizes continue to decrease, the aspect ratio, (e.g., the ratio of height/depth to width) of features such as vias generally increases. Otherwise, the via can fail, possibly causing failure of the entire IC. In these embodiments, qubits are operatively coupled to the topside of an interposer which is then connected by TSVs to a multilevel wiring layer on the backside of the interposer.

System 100 can be any suitable computing device or set of computing devices that can be communicatively coupled to devices, non-limiting examples of which can include, but are not limited to, a server computer, a computer, a mobile computer, a mainframe computer, an automated testing system, a network storage device, a communication device, a web server device, a network switching device, a network routing device, a gateway device, a network hub device, a network bridge device, a control system, or any other suitable computing device. A device can be any device that can communicate information with the systems 100 and/or any other suitable device that can employ information provided by system 100. It is to be appreciated that systems 100, components, models or devices can be equipped with communication components (not shown) that enable communication between the system, components, models, devices, etc. over one or more networks.

The various components of systems 100 can be connected either directly or via one or more networks. Such networks can include wired and wireless networks, including, but not limited to, a cellular network, a wide area network (WAN) (e.g., the Internet), or a local area network (LAN), non-limiting examples of which include cellular, WAN, wireless fidelity (Wi-Fi), Wi-Max, WLAN, radio communication, microwave communication, satellite communication, optical communication, sonic communication, or any other suitable communication technology. Moreover, the aforementioned systems and/or devices have been described with respect to interaction between several components. It may be appreciated that such systems and components can include these components or sub-components specified therein, some of the specified components or sub-components, and/or additional components. Sub-components may also be implemented as components communicatively coupled to other components rather than included within parent components. Further yet, one or more components and/or sub-components can be combined into a single component providing aggregate functionality. The components can also interact with one or more other components not specifically described herein for the sake of brevity, but known by those of skill in the art.

The subject computer processing systems, methods apparatuses and/or computer program products can be employed to solve new problems that arise through advancements in technology, computer networks, the Internet and the like.

Quantum circuits input/output connections have increased demand in size and complexity. There is continued progress being made for 3D integration and radio-frequency packaging techniques. Moreover, there are other developed technologies in the field of circuit QED from room temperature microwave devices and complex superconducting circuits. There are many proposals implemented for multi-layer microwave integrated quantum circuit architecture that adapts existing circuit design and other fabrication techniques. Quantum information processing is developing rapidly in many implementations and in particular superconducting quantum circuits. Superconducting quantum circuits have challenges that prevent a scaling strategy similar to that of classical integrated circuits. Qubits strong electromagnetic interactions allow efficient entanglement and control and susceptible to degraded quantum information. The resulted crosstalk is due to undesirable mixing of quantum states or decoherence. Thus, it is desirable to prevent crosstalk effects as high-Q qubits (Q≈10⁶-10⁹) may also be coupled to high-speed, low-Q (Q≈10³) elements for readout, control, and feedback.

Turning back to the quantum circuit packaging 200 of FIG. 2, in general, electronic components may be connected together through different techniques. One such method is through wire bonding. Wire bonding is a well-known technique for forming electrical interconnections between an electronic component such as a printed circuit board (PCB) or an integrated circuit (IC). As shown, the quantum circuit package 200 includes qubit chips with inward facing surfaces utilized for devices and signal delivery/readout. A quantum circuit typically has a 2D array of qubits. This architecture in FIG. 2 is an example multi-layer superconducting device. In current designs, a qubit may require (on average) anywhere from ˜1.1 to 3 or more wires wherein a chip with (e.g., 1000 qubits) would require upwards of 3000 wires. In a conventional method of assembling quantum devices, a chip with qubits is bump bonded to an interposer chip. As illustrated herein, embodiments address how to provide high quality connections with a low cross talk from potentially hundreds of qubits within a single silicon chip. This packaged circuit 200 consists of a qubit carrier wafer 202 (or handler). A wafer is also known as a substrate and this substrate is a thin slice of semiconductor utilized as fabrication for integrated circuits. The qubit wafer 204 is UBM (Under Bump Metallurgy Interposer pad) bump bonded 206 to an interposer wafer 208. The interposer TSVs 209 provide grounding (isolation), mode control, and carry signals down to the backside of the thinned interposer chip. The qubit wafer QM0 204 which is bump bonded 206 to interposer wafer IM0 208 that has MLM1 211 protected by MLM0 210 and MLM2 213 as ground planes. The backside wiring is also known as multi-level wiring (MLW) acts as a redistribution layer. The TSVs carry signals back to the interposer surface 212 where signals are accessed. Thus, the connections to and from the signal TSVs are designed to minimize reflections. The qubit wafer 204 is utilized for qubits and the interconnections which allow qubits to entangle. The interposer surface 208 is utilized for readout resonators, filters, feed and readout lines. The bump bonds 206 are connected to the qubit wafer 204 and are formed from a low temperature solder material and provided with a size and/or shape that enables an electrical connection to be made at point of contact. The bump bonds 206 may be utilized to mechanically and electrically connect an electronic connector (e.g., direct current (DC) signals and/or radio frequency (RF) signals) to a first substrate. The bump bonds 206 can also be utilized to mechanically and electrically connect the first substrate to a second substrate. A multi-layer topology is proposed to ensure cross talk is reduced and produce high quality connection. Moreover, the connections within the interposer wafer to the metal lines underneath allow for complex signal transfer.

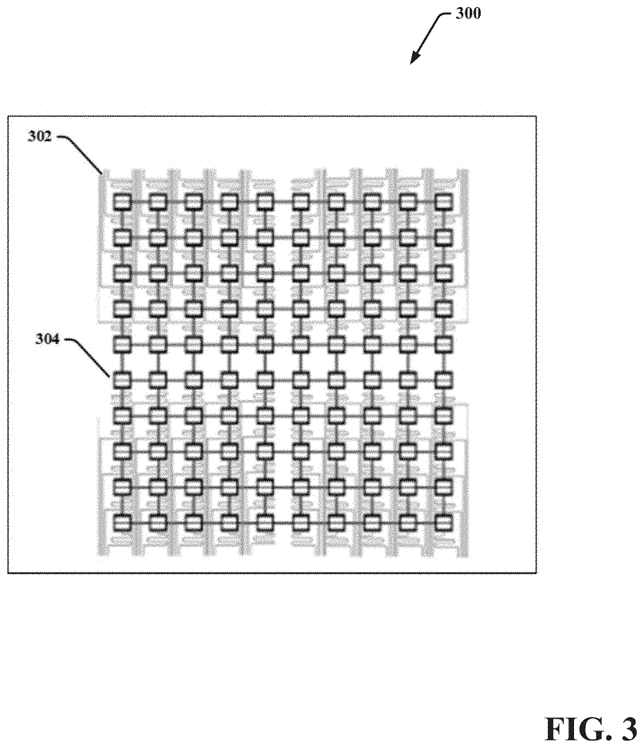

FIG. 3 illustrates an example qubit chip surface top view lattice. In this conventional architecture for the qubits and readout resonators, a third layer of wiring below the interposer is added which is accessed by TSVs. This third layer is superconducting, lossy at RF frequencies due to the presence of encapsulating dielectrics and is shielded through the use of continuous ground planes above and below the signal lines. In the qubit chip surface 300, the qubits are black squares 304. In the qubit chip surface 300, the red lines 302 are readout resonators. These resonators typically reside on the interposer chip 206 and the wires 302 typically allow to program a qubit. The qubit connections on the qubit chip from this lattice allow to entangle qubits. The intersecting patterns of red and black lines means that the bump bonds can be utilized to provide crossovers in these locations. The addition of third layer has the desirable property of removing the signal lines from proximity to either qubits or wiring connecting to these qubits. These signal lines could, if left in place on the interposer, cause significant cross-talk (signal leaking to the wrong qubits). Moreover, quality of this connection would be degraded if the lattice is spanned across the chip. It becomes challenging to have long range connections entangled between the black layer simultaneously connected to neighbours. This type of intersection of wires may also cause a short circuit. These connections are single photon interaction between qubits wherein the red signals are high power signals and there are very low signals between the qubits. For example, if a program signal with high frequency microwave pulses are chosen and as the resonators 302 are in proximity with the black lines/qubits 304 then the other qubits that are also in the proximity are compromised while trying to program the one qubit in question.

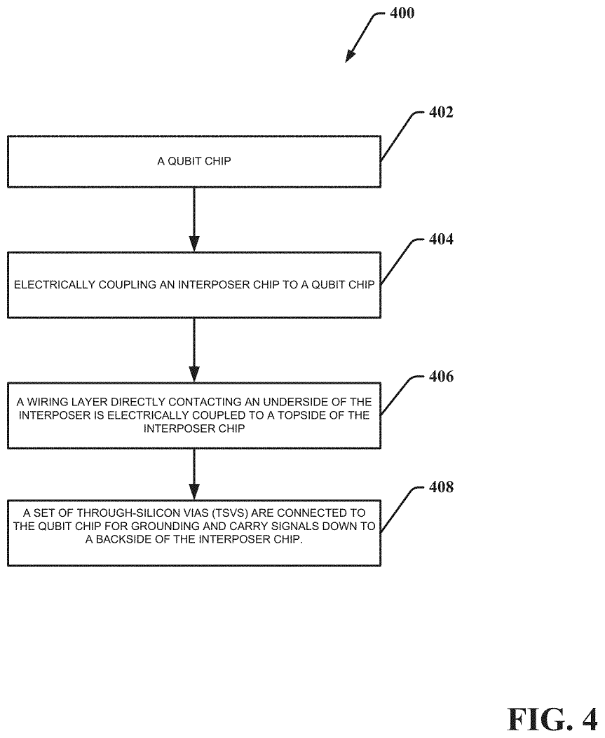

FIG. 4 illustrates an example 400 flowchart for creating an improved multi-layered packaging for quantum circuits. As currently practiced, quantum chips have access to two high-quality surfaces connected by bump bonds. One surface is typically utilized for qubits and interconnects, and the second is utilized for readout resonators and feedlines. Quantum computing may require thousands of qubits in a lattice, and the associated wiring may not be feasible with current packaging schemes, both for sheer number and crosstalk. Superconducting multilayer wiring has been developed for classical digital superconducting logic at many organizations. However, the lossy dielectric materials associated with these processes may not be compatible with low-loss portions of superconducting quantum circuits. One approach to solve this problem is to develop a multilayer superconducting wiring package for quantum circuits. At 402, a qubit chip layer is operatively coupled to the first chip layer (e.g., with a set of bump-bonds or capacitive coupling). An interposer chip 404 includes a first through-substrate-via electrically coupled (e.g., bump bonded) to a qubit chip. The interposer chip is connected to a Printed Circuit Board (PCB), laminate or flex using periphery bump bonds on a top surface of the interposer layer wherein the periphery bonds are electrically connected to the wiring layer. Moreover, at 406, a multi-level wiring (MLW) layer is directly contacting an underside of the interposer chip and the TSV(s) provide an electrical signal connection from a top side of the interposer chip to the wiring layer. The wiring layer comprises a multilayer wiring structure with interlayer and superconducting layers. This multi-level wiring (MLW) facilitates complex routing and effective radio frequency transmission wherein a backside multi-level wiring performs as a redistribution layer. At 408, a set of TSVs is connected to the qubit chip for grounding. The TSVs on the qubit chip are passive such that no current flows through them in operating the chip. It is present to prevent ‘chip modes’ in potentially large qubit chips. The connections to and from TSV signals are designed to minimize reflections. The characteristic impedance of the MLW, TSV, and routing on the interposer chip are matched to facilitate signal routing. MLW connections have attenuation constants in the range of 0.1-2 Nepers/meter (as compared to “high-quality” layers (IM0, QM0) which range˜0.0001-0.001 Nepers/meter).

FIG. 5 illustrates an example of a multi-layer superconducting device. As noted above in FIG. 2, the structure has a qubit carrier wafer (or qubit chip handler) 502, a qubit wafer 504 is bump bonded 506 to an interposer wafer 508 and TSVs 509. As illustrated in 500, the interposer wafer 508 is also bump bonded to a PCB 507, 509 or similar circuit and the signals are extracted. In the case of a 1000-qubit chip, and 3000 wires escaping to the periphery of the interposer chip, it is not possible to achieve high cross-talk rejection while extracting along the interposer surface and then onto the PCB circuit. Thus, a perimeter of the interposer chip is connected to a Printed Circuit Board (PCB) 507 and 509, laminate or flex using periphery bump bonds 506 on a top surface of the interposer layer 508 wherein the periphery bonds are electrically connected to the wiring layer. TSVs are utilized to access the multilevel wiring layer on the back of interposer wafer 508. The qubit wafer QM0 504 which is bump bonded 506 to interposer wafer IM0 508 and TSVs 509 and protects MLM1 513 by MLM0 510 and MLM2 514 as ground planes. The device 500 includes an interposer carrier wafer (or interposer handler) 512. Adding MLM1 513 as a third wiring redistribution signal layer can facilitate low Q resonator structures.

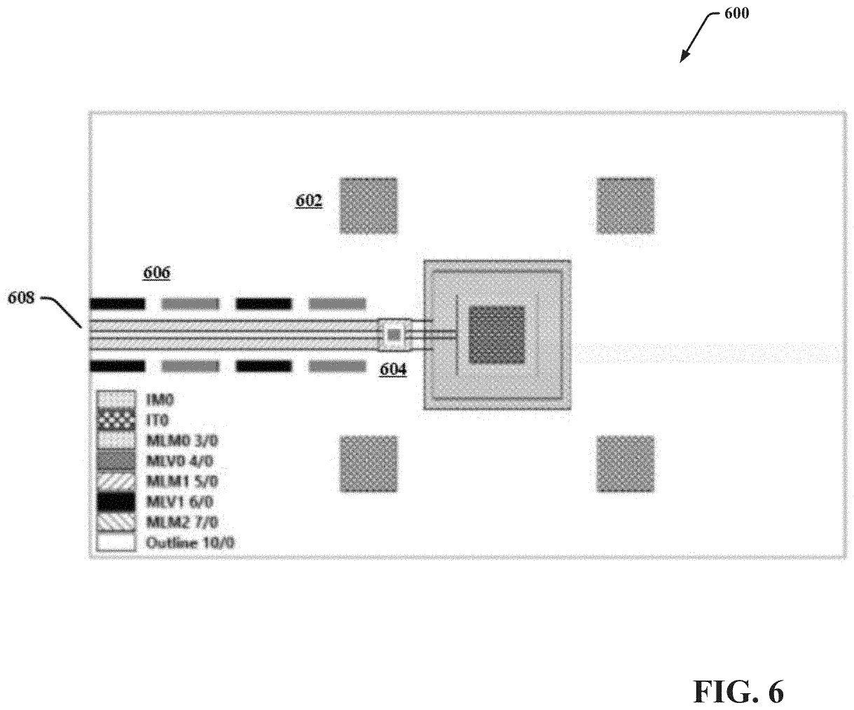

FIG. 6 illustrates an example schematic within interposer wafer 600. A novelty of embodiments is within the interposer wafer wherein ITO is connected to metal lines that allow for complex signal transfer. As illustrated in 600, the schematic consists of MLV0 602 along with MLV1 606. Moreover, transmission from IM0 604 to MLM1 608 is transparent and reduces cross talk by keeping lines isolated from one another. IM0 604 is connected between ML0 and ML1; this may aid to avoid extra capacitance or conductance along the line. Characteristic impedance on metal layers and TSVs are relevant to this type of signal routing. The TSVs multi-level wiring and the external circuitry may have same impedance, e.g., typically 50 ohms. Another possibility of these embodiments is that the qubit wafer may not necessarily need to have TSVs in it. If a qubit chip is relatively small, the chip modes are high enough in frequency such that they do not interfere with the operation of the qubits. This means generally that the chip mode frequencies are higher than ˜10 GHz (in order to be well above either qubit or resonator frequencies). The frequencies of these chip modes are set by the dimensions of the chip which limits the chip to approximately 1 cm square or smaller, given the dielectric properties of silicon. If the chip is sufficiently small, the TSVs may not be utilized and thus both bonding adhesive and qubit carrier wafer can be eliminated from the architecture. Integration of multi-level superconducting TSVs with superconducting qubits in a quantum device facilitates low crosstalk even with a high density of signal carrying lines. The qubit chip has TSVs for grounding purposes and more than one level of MLW is utilized to allow complicated routing. The characteristic impedance of the MLW, TSV, and routing on the interposer chip are matched to facilitate signal routing. Also, the detailed connection between TSVs on the interposer chip and multilevel wiring provides effective radio frequency transmission. As superconducting qubit circuits become complex, addressing a large array of qubits becomes a challenge. Thus, these embodiments herein propose an effective multi-layered packaged architecture for quantum circuits to support complex densely-packed qubit systems without compromising the qubit performance, low-loss signal, and cross talk. Moreover, the connections within the interposer wafer to the metal lines underneath allow for complex signal transfer. Prior art mainly focuses on metal-metal bond in cavities and coupling to a 3D cavity. However, these embodiments focus on using backside wiring (MLW) to act as a redistribution layer and minimize reflections.

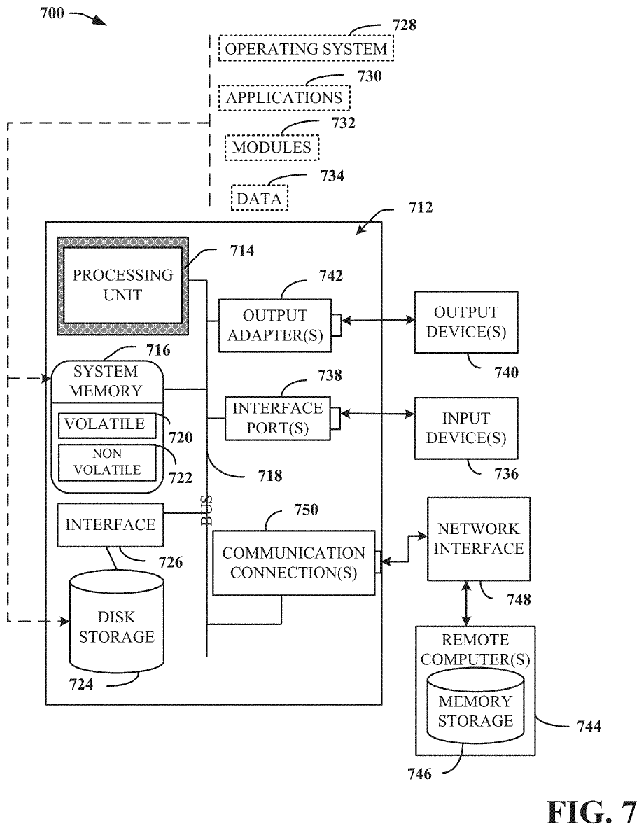

To provide a context for the various aspects of the disclosed subject matter, FIG. 7 as well as the following discussion are intended to provide a general description of a suitable environment in which the various aspects of the disclosed subject matter can be implemented. FIG. 7 illustrates a block diagram of an example, non-limiting operating environment in which one or more embodiments described herein can be facilitated. Repetitive description of like elements employed in other embodiments described herein is omitted for sake of brevity.

With reference to FIG. 7, a suitable operating environment 700 for implementing various aspects of this disclosure can also include a computer 712. The computer 712 can also include a processing unit 714, a system memory 716, and a system bus 718. The system bus 718 couples system components including, but not limited to, the system memory 716 to the processing unit 714. The processing unit 714 can be any of various available processors. Dual microprocessors and other multiprocessor architectures also can be employed as the processing unit 714. The system bus 718 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Firewire (IEEE 1394), and Small Computer Systems Interface (SCSI).

The system memory 716 can also include volatile memory 720 and non-volatile memory 722. The basic input/output system (BIOS), containing the basic routines to transfer information between elements within the computer 712, such as during start-up, is stored in non-volatile memory 722. Computer 712 can also include removable/non-removable, volatile/non-volatile computer storage media. FIG. 7 illustrates, for example, a disk storage 724. Disk storage 724 can also include, but is not limited to, devices like a magnetic disk drive, floppy disk drive, tape drive, Jaz drive, Zip drive, LS-100 drive, flash memory card, or memory stick. The disk storage 724 also can include storage media separately or in combination with other storage media. To facilitate connection of the disk storage 724 to the system bus 718, a removable or non-removable interface is typically utilized, such as interface 726. FIG. 7 also depicts software that acts as an intermediary between users and the basic computer resources described in the suitable operating environment 700. Such software can also include, for example, an operating system 728. Operating system 728, which can be stored on disk storage 724, acts to control and allocate resources of the computer 712.

System applications 730 take advantage of the management of resources by operating system 728 through program modules 732 and program data 734, e.g., stored either in system memory 716 or on disk storage 724. It is to be appreciated that this disclosure can be implemented with various operating systems or combinations of operating systems. A user enters commands or information into the computer 712 through input device(s) 736. Input devices 736 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 714 through the system bus 718 via interface port(s) 738. Interface port(s) 738 include, for example, a serial port, a parallel port, a game port, and a universal serial bus (USB). Output device(s) 740 utilize some of the same type of ports as input device(s) 736. Thus, for example, a USB port can be utilized to provide input to computer 712, and to output information from computer 712 to an output device 740. Output adapter 742 is provided to illustrate that there are some output devices 740 like monitors, speakers, and printers, among other output devices 740, which require special adapters. The output adapters 742 include, by way of illustration and not limitation, video and sound cards that provide a means of connection between the output device 740 and the system bus 718. It is to be noted that other devices and/or systems of devices provide both input and output capabilities such as remote computer(s) 744.

Computer 712 can operate in a networked environment using logical connections to one or more remote computers, such as remote computer(s) 744. The remote computer(s) 744 can be a computer, a server, a router, a network PC, a workstation, a microprocessor-based appliance, a peer device or other common network node and the like, and typically can also include many or all of the elements described relative to computer 712. For purposes of brevity, only a memory storage device 746 is illustrated with remote computer(s) 744. Remote computer(s) 744 is logically connected to computer 712 through a network interface 748 and then physically connected via communication connection 750. Network interface 748 encompasses wire and/or wireless communication networks such as local-area networks (LAN), wide-area networks (WAN), cellular networks, etc. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL). Communication connection(s) 750 refers to the hardware/software employed to connect the network interface 748 to the system bus 718. While communication connection 750 is shown for illustrative clarity inside computer 712, it can also be external to computer 712. The hardware/software for connection to the network interface 748 can also include, for exemplary purposes only, internal and external technologies such as, modems including regular telephone grade modems, cable modems and DSL modems, ISDN adapters, and Ethernet cards.

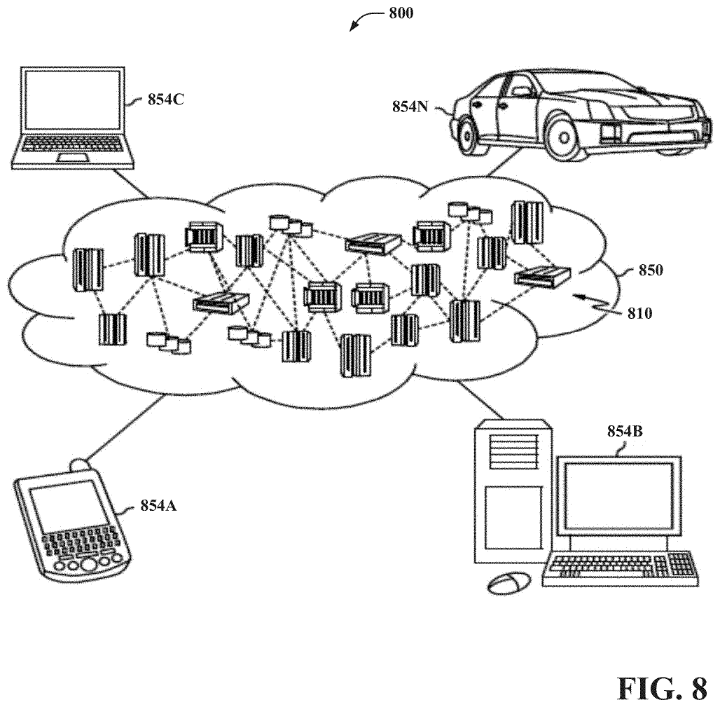

Referring now to FIG. 8 an illustrative cloud computing environment 850 is depicted. As shown, cloud computing environment 850 includes one or more cloud computing nodes 810 with which local computing devices utilized by cloud consumers, such as, for example, personal digital assistant (PDA) or cellular telephone 854A, desktop computer 854B, laptop computer 854C, and/or automobile computer system 854N may communicate. Although not illustrated in FIG. 8, cloud computing nodes 810 can further comprise a quantum platform (e.g., quantum computer, quantum hardware, quantum software, etc.) with which local computing devices utilized by cloud consumers can communicate. Nodes 810 may communicate with one another. It may be grouped (not shown) physically or virtually, in one or more networks, such as Private, Community, Public, or Hybrid clouds as described hereinabove, or a combination thereof. This allows cloud computing environment 850 to offer infrastructure, platforms and/or software as services for which a cloud consumer does not need to maintain resources on a local computing device. It is understood that the types of computing devices 854A-N shown in FIG. 8 are intended to be illustrative only and that computing nodes 810 and cloud computing environment 850 can communicate with any type of computerized device over any type of network and/or network addressable connection (e.g., using a web browser).

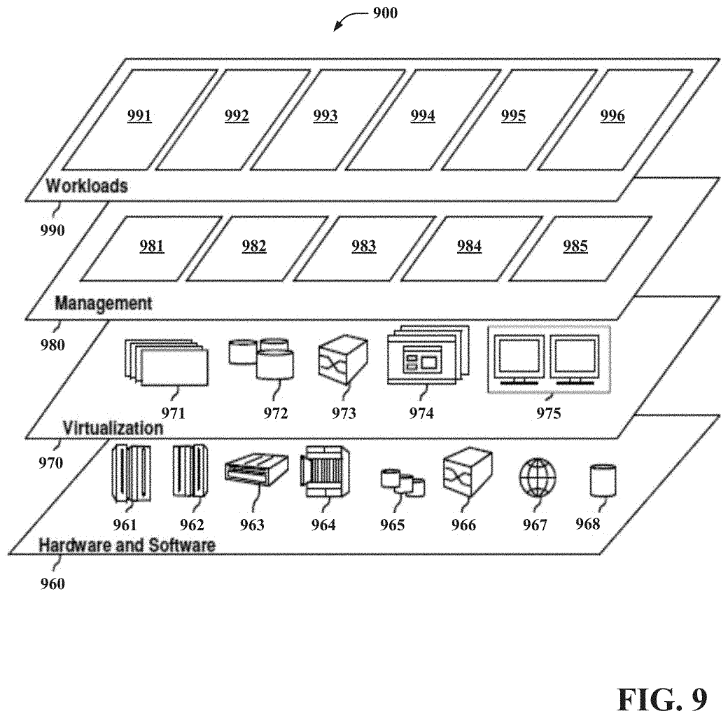

Referring now to FIG. 9, a set of functional abstraction layers provided by cloud computing environment 850 (FIG. 8) is shown. It should be understood in advance that the components, layers, and functions shown in FIG. 9 are intended to be illustrative only and embodiments of the invention are not limited thereto. As depicted, the following layers and corresponding functions are provided:

Hardware and software layer 960 includes hardware and software components. Examples of hardware components include: mainframes 961; RISC (Reduced Instruction Set Computer) architecture-based servers 962; servers 963; blade servers 964; storage devices 965; and networks and networking components 966. In some embodiments, software components include network application server software 967, quantum platform routing software 968, and/or quantum software (not illustrated in FIG. 9).

Virtualization layer 970 provides an abstraction layer from which the following examples of virtual entities may be provided: virtual servers 971; virtual storage 972; virtual networks 973, including virtual private networks; virtual applications and operating systems 974; and virtual clients 975.

In one example, management layer 980 may provide the functions described below. Resource provisioning 981 provides dynamic procurement of computing resources and other resources that are utilized to perform tasks within the cloud computing environment. Metering and Pricing 982 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 983 provides access to the cloud computing environment for consumers and system administrators. Service level management 984 provides cloud computing resource allocation and management such that required service levels are met. Service Level Agreement (SLA) planning and fulfillment 985 provide pre-arrangement for, and procurement of, cloud computing resources for which a future requirement is anticipated in accordance with an SLA.

Workloads layer 990 provides examples of functionality for which the cloud computing environment may be utilized. Non-limiting examples of workloads and functions which may be provided from this layer include: mapping and navigation 991; software development and lifecycle management 992; virtual classroom education delivery 993; data analytics processing 994; transaction processing 995; and quantum state preparation software 996.

The present invention may be a system, a method, an apparatus and/or a computer program product at any possible technical detail level of integration. The computer program product can include a computer readable storage medium (or media) having computer readable program instructions thereon for causing a processor to carry out aspects of the present invention. The computer readable storage medium can be a tangible device that can retain and store instructions for utilize by an instruction execution device. The computer readable storage medium can be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium can also include the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as utilized herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in computing/processing device receives computer readable program instructions from the network and forwards the computer readable program instructions for storage in a computer readable storage medium within the respective computing/processing device. Computer readable program instructions for carrying out operations of the present invention can be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions can execute entirely on the user's computer, partly on the user's computer, as a stand-alone software package, partly on the user's computer and partly on a remote computer or entirely on the remote computer or server. In the latter scenario, the remote computer can be connected to the user's computer through any type of network, including a local area network (LAN) or a wide area network (WAN), or the connection can be made to an external computer (for example, through the Internet using an Internet Service Provider). In some embodiments, electronic circuitry including, for example, programmable logic circuitry, field-programmable gate arrays (FPGA), or programmable logic arrays (PLA) can execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It can be understood that a block of the flowchart illustrations and/or block diagrams, and combinations of blocks in the flowchart illustrations and/or block diagrams, can be implemented by computer readable program instructions. These computer readable program instructions can be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions can also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks. The computer readable program instructions can also be loaded onto a computer, other programmable data processing apparatus, or other device to cause a series of operational acts to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, a block in the flowchart or block diagrams can represent a module, segment, or portion of instructions, which comprises one or more executable instructions for implementing the specified logical function(s). In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved. It can also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

While the subject matter has been described above in the general context of computer-executable instructions of a computer program product that runs on a computer and/or computers, those skilled in the art may recognize that this disclosure also can or can be implemented in combination with other program modules. Generally, program modules include routines, programs, components, data structures, etc. that perform particular tasks and/or implement particular abstract data types. Moreover, those skilled in the art may appreciate that the inventive computer-implemented methods can be practiced with other computer system configurations, including single-processor or multiprocessor computer systems, mini-computing devices, mainframe computers, as well as computers, hand-held computing devices (e.g., PDA, phone), microprocessor-based or programmable consumer or industrial electronics, and the like. The illustrated aspects can also be practiced in distributed computing environments in which tasks are performed by remote processing devices that are linked through a communications network. However, some, if not all aspects of this disclosure can be practiced on stand-alone computers. In a distributed computing environment, program modules can be located in both local and remote memory storage devices.

As utilized in this application, the terms “component,” “system,” “platform,” “interface,” and the like, can refer to and/or can include a computer-related entity or an entity related to an operational machine with one or more specific functionalities. The entities disclosed herein can be either hardware, a combination of hardware and software, software, or software in execution. For example, a component can be, but is not limited to being, a process running on a processor, a processor, an object, an executable, a thread of execution, a program, and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which is operated by a software or firmware application executed by a processor. In such a case, the processor can be internal or external to the apparatus and can execute at least a part of the software or firmware application. As yet another example, a component can be an apparatus that provides specific functionality through electronic components without mechanical parts, wherein the electronic components can include a processor or other means to execute software or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as utilized in the subject specification and annexed drawings should generally be construed to mean “one or more” unless specified otherwise or clear from context to be directed to a singular form. As utilized herein, the terms “example” and/or “exemplary” are utilized to mean serving as an example, instance, or illustration. For the avoidance of doubt, the subject matter disclosed herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit or device comprising, but not limited to, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. Further, processors can exploit nano-scale architectures such as, but not limited to, molecular and quantum-dot based transistors, switches and gates, in order to optimize space usage or enhance performance of user equipment. A processor can also be implemented as a combination of computing processing units. In this disclosure, terms such as “store,” “storage,” “data store,” data storage,” “database,” and substantially any other information storage component relevant to operation and functionality of a component are utilized to refer to “memory components,” entities embodied in a “memory,” or components comprising a memory. It is to be appreciated that memory and/or memory components described herein can be either volatile memory or non-volatile memory, or can include both volatile and non-volatile memory. By way of illustration, and not limitation, non-volatile memory can include read only memory (ROM), programmable ROM (PROM), electrically programmable ROM (EPROM), electrically erasable ROM (EEPROM), flash memory, or non-volatile random-access memory (RAM) (e.g., ferroelectric RAM (FeRAM). Volatile memory can include RAM, which can act as external cache memory, for example. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM), and Rambus dynamic RAM (RDRAM). Additionally, the disclosed memory components of systems or computer-implemented methods herein are intended to include, without being limited to including, these and any other suitable types of memory.

What has been described above include mere examples of systems and computer-implemented methods. It is, of course, not possible to describe every conceivable combination of components or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are utilized in the detailed description, claims, appendices and drawings such terms are intended to be inclusive in a manner similar to the term “comprising” as “comprising” is interpreted when employed as a transitional word in a claim.

The descriptions of the various embodiments have been presented for purposes of illustration, but are not intended to be exhaustive or limited to the embodiments disclosed. Many modifications and variations maybe apparent to those of ordinary skill in the art without departing from the scope and spirit of the described embodiments. The terminology utilized herein was chosen to best explain the principles of the embodiments, the practical application or technical improvement over technologies found in the marketplace, or to enable others of ordinary skill in the art to understand the embodiments disclosed herein.

What is claimed is:

1. A quantum semiconductor device, comprising:
a qubit chip;
an interposer chip, with a handler, including a through-silicon-via (TSV) coupled to a top surface of the interposer chip through bump bonds to a bottom surface of the qubit chip; and
a multi-level wiring (MLW) layer contacting an underside of the interposer chip and coupling to the top side of the handler, the TSV facilitating an electrical signal connection between the MLW layer, a topside of the interposer chip and the qubit chip, wherein structure of the device mitigates signal cross-talk across respective lines of the MLW layer.

2. The device of claim 1, wherein the TSV provides an electrical signal connection from the MLW layer to the topside of the interposer chip.

3. The device of claim 1, wherein the interposer chip is connected to a printed circuit board (PCB), laminate or flex wiring harness using periphery bump bonds on the top side of the interposer chip.

4. The device of claim 3, wherein the periphery bump bonds are electrically connected to the wiring layer.

5. The device of claim 1, wherein the MLW layer comprises a multilayer wiring structure with interlayer and superconducting layers.

6. The device of claim 1, wherein the MLW layer facilitates complex routing and effective radio frequency transmission.

7. The device of claim 6, wherein a backside of the MLW layer performs as a redistribution wiring layer.

8. The device of claim 1, wherein connections to and from the TSV minimize reflections.

9. The device of claim 1, wherein a characteristic impedance of the MLW, the TSV, and routing on the interposer chip are matched to facilitate signal routing.

10. A method, comprising:
forming a qubit chip;
forming an interposer chip, with a handler, including a through-silicon-via (TSV) coupled to a top surface of the interposer chip through bump bonds to a bottom surface of the qubit chip;
forming a multi-level wiring (MLW) layer contacting an underside of the interposer chip and coupling to the top side of the handler, the TSV facilitating an electrical signal connection between the MLW layer, a topside of the interposer chip and the qubit chip, wherein structure of the device mitigates signal cross-talk across respective lines of the MLW layer.

11. The method of claim 10, further comprising utilizing the TSV to provide an electrical signal connection from the MLW layer to the topside of the interposer chip.

12. The method of claim 10, further comprising connecting the interposer chip to a printed circuit board (PCB), laminate or flex wiring harness using periphery bump bonds on the top side of the interposer chip.

13. The method of claim 12, further comprising electrically coupling the periphery bump bonds to the MLW layer.

14. The method of claim 10, further comprising coupling a wiring layer with a multilayer wiring structure with interlayer and superconducting layers.

15. The method of claim 10, further comprising utilizing the MLW layer to facilitate complex routing and effective radio frequency transmission.

16. The method of claim 15, further comprising utilizing a backside of the MLW layer to perform as a redistribution wiring layer.

17. The device of claim 10, further comprising utilizing connections to and from the TSV to minimize reflections.

18. The device of claim 10, further comprising matching a characteristic impedance of the MLW, the TSV, and routing on the interposer chip to facilitate signal routing.

19. A quantum semiconductor device, comprising:
an interposer chip, with a handler, including a through-substrate-via (TSV), bump bonded to a qubit chip;
a multi-level wiring (MLW) layer, contacting an underside of the interposer chip and coupling to the top side of the handler, the TSV facilitating an electrical signal connection between the MLW layer, a topside of the interposer chip and the qubit chip, wherein structure of the device mitigates signal cross-talk across respective lines of the MLW layer; and
a set of through-silicon vias (TSVs) connected to the qubit chip for grounding and carrying signals down to a backside of the interposer chip;
wherein the interposer chip comprises a second TSV that provides an electrical signal connection from the wiring layer to the top side of the interposer chip.

20. The device of claim 19 wherein the interposer chip is connected to a printed circuit board (PCB), laminate or flex wiring harness using periphery bump bonds on the top side of the interposer chip.
